(19) United States
(12) Patent Application Publication
(10) Pub. No.: US 2010/0052156 A1
(43) Pub. Date: Mar. 4, 2010

(54) CHIP SCALE PACKAGE STRUCTURE AND FABRICATION METHOD THEREOF

(75) Inventors: Bernd Karl Appelt, Gulf Breeze, FL (US); Bradford J. Factor, Paris (FR)

Correspondence Address: J C PATENTS, 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 12/199,121

(22) Filed: Aug. 27, 2008

(51) Int. Cl. H01L 23/36; H01L 21/56

(52) U.S. Cl. 257/712; 438/114; 257/E23.101; 257/E21.502

(57) ABSTRACT

A chip scale package (CSP) structure and the packaging process thereof are described. By using a matrix of interlinked heat sink units compatible with the block substrate, the packaging process can be simplified and a plurality of packages units or chip scale packages with enhanced thermal performance can be obtained after singulation.

### BACKGROUND OF THE INVENTION

1. Field of Invention

The present invention relates to a chip package structure and the fabrication method thereof. More particularly, the present invention relates to a chip scale package (CSP) structure and the fabrication method thereof.

2. Description of Related Art

Along with the size shrinkage of chips, increased operation speeds of electronic devices and high-level package density, the amount of heat generated within a semiconductor package has been increased considerably. In order to improve the heat dissipation ability of the package structure, it is common to employ a heat dissipation plate or a heat sink for assisting heat dissipation of the chip.

Taking the conventional ball grid array (BGA) package structure as an example, a heat spreader is placed above the chip and adhered to the substrate by an adhesive material. However, the packaging process is laborious and time-consuming as each heat spreader is placed over the chip one by one.

Various package technologies have been developed in order to meet the quality demands for different package structures, and one of the well-developed packaging technologies is chip scale package (CSP). The aforementioned CSP techniques can reduce the dimension of the package structure to a size only slightly larger than the original size of the chip. However, the heat dissipation issues become more critical as the CSP structure is compact.

### SUMMARY OF THE INVENTION

The present invention provides a package structure with matrix heat sink, which employs a matrix or a network of interconnected heat sink units over the chips for assisting heat dissipation of the package structure.

The present invention relates to a packaging process for fabricating a chip scale package structure with good heat dissipation ability. By using the matrix heat sink, the placement and attachment of the heat sink for the packaging process is simplified and becomes less labor-demanding. Furthermore, the packaging process is compatible with the existing packaging processes and/or the packaging tool sets.

The present invention provides a package structure, comprising a substrate having a plurality of substrate units, a plurality of chips, a matrix heat sink having a plurality of heat sink units interlinked with one another, and a molding compound. The matrix heat sink is disposed over the substrate and covering the chips, and each heat sink unit corresponds to at least one chip and one substrate unit. The molding compound covers the substrate and the matrix heat sink and fills between the matrix heat sink, the chips and the substrate.

According to an embodiment of the present invention, each heat sink unit has a body portion located on top of and attached to the chip, an extended portion attached to the substrate unit and a slant portion connecting the body portion and the extended portion.

According to an embodiment of the present invention, the top surface of the body portion in the heat sink unit can be exposed by the molding compound for better heat dissipation.

According to an embodiment of the present invention, after singulation, the package structure is singulated into a plurality of package units or chip scale packages. The chip scale package includes a substrate unit, at least one chip, a heat sink unit and a portion of the molding compound. For the package unit or chip scale package, an end of the extended portion of the heat sink unit is exposed from the molding compound and a sidewall of the cut molding compound is aligned with a sidewall of the substrate unit.

According to an embodiment of the present invention, a bond film is further included between the heat sink unit and the chip. The chip can be electrically connected to the substrate unit through bumps or wires.

According to an embodiment of the present invention, thermally conductive fillers can be further added to the molding compound and/or the bond film for enhancing heat dissipation efficiency.

The present invention relates to a packaging process comprising providing a substrate, mounting a plurality of chips to the substrate, placing and attaching a matrix heat sink having a plurality of heat sink units interlinked with one another, on the chips and over the substrate, forming a molding compound and cutting through the molding compound, the matrix heat sink and the substrate to form a plurality of package units.

According to the above method described in an embodiment of the present invention, the chip can be electrically connected to the substrate unit through flip chip technology or wire bonding technology.

In view of the above, as the matrix heat sink is used, better heat dissipation is achieved along with straightforward and simple process steps. The reliability of the resultant package structure is improved and the production yield is increased.

In order to make the aforementioned and other objectives, features and advantages of the present invention comprehensible, preferred embodiments accompanied with figures are described in detail below.

### BRIEF DESCRIPTION OF THE DRAWINGS

FIG. 1A is a top view of a package substrate according to one embodiment of the invention.

FIG. 1B is a schematic partial view of a matrix heat sink according to one embodiment of the invention.

FIG. 2A-2E are schematic cross-sectional views showing steps of a chip scale packaging process according to one embodiment of the invention.

FIG. 2F is a schematic cross-sectional view showing a chip scale package structure after singulation according to one embodiment of the invention.

FIG. 2G is a schematic cross-sectional view showing a chip scale package structure after singulation according to another embodiment of the present invention.

### DESCRIPTION OF EMBODIMENTS

Reference will now be made in detail to the present preferred embodiments of the invention, examples of which are illustrated in the accompanying drawings.

The following preferred embodiments focus on chip scale package (CSP) technology as examples, but the scope of the present invention will not be limited by the descriptions or embodiments herein. In addition to CSP technology, wafer-level chip scale package (WLCSP) technology, ball grid array (BGA) technology or area-array flip chip technology may be applicable for fabricating the package structure encompassed with the scope of this invention. Moreover, a variety of techniques of the CSP technology, such as, the single chip package, the stack chip package and the planar multi-chip package (MCM) may also be applicable if considered appropriate.

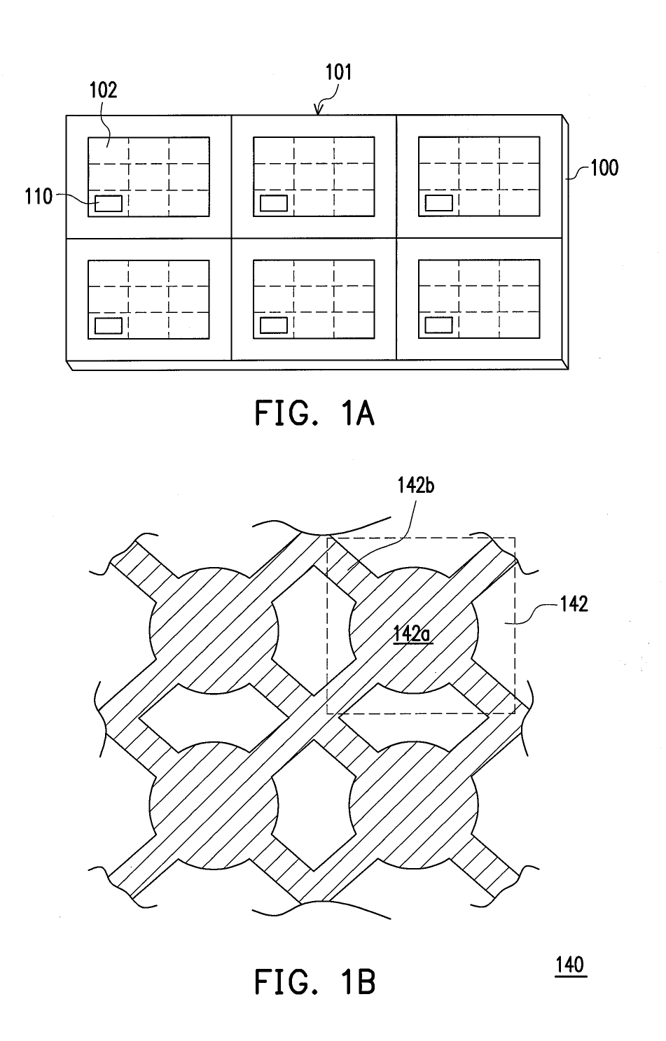

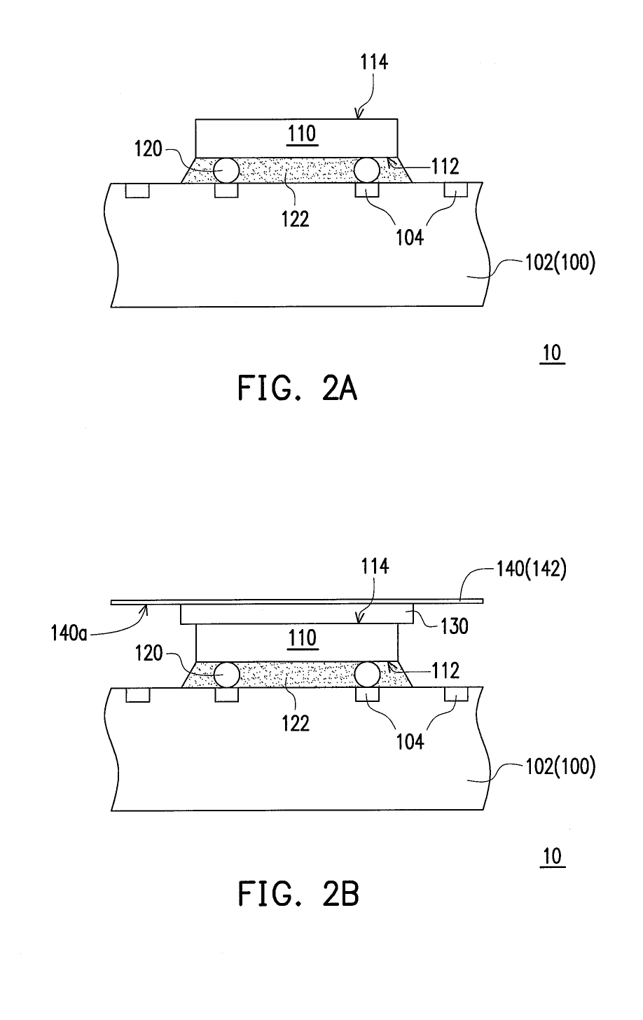

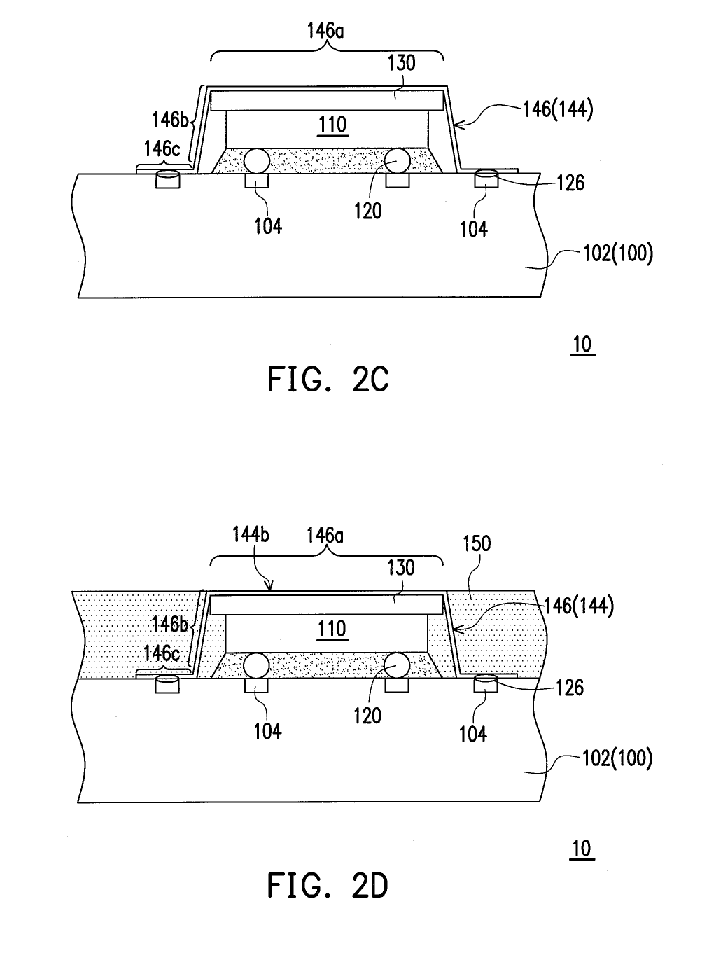

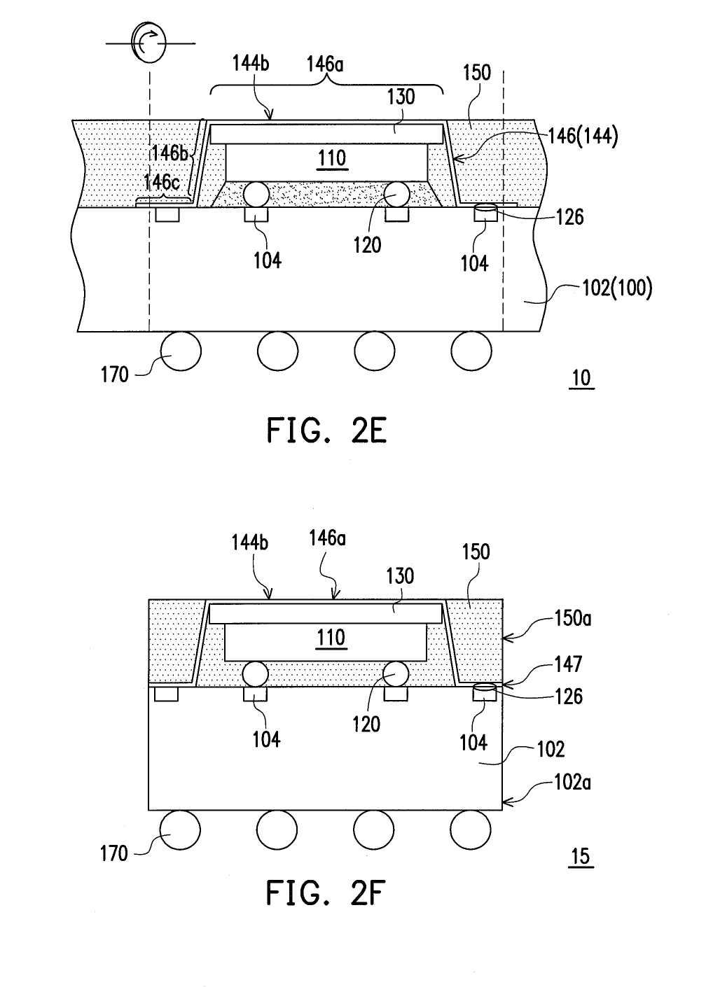

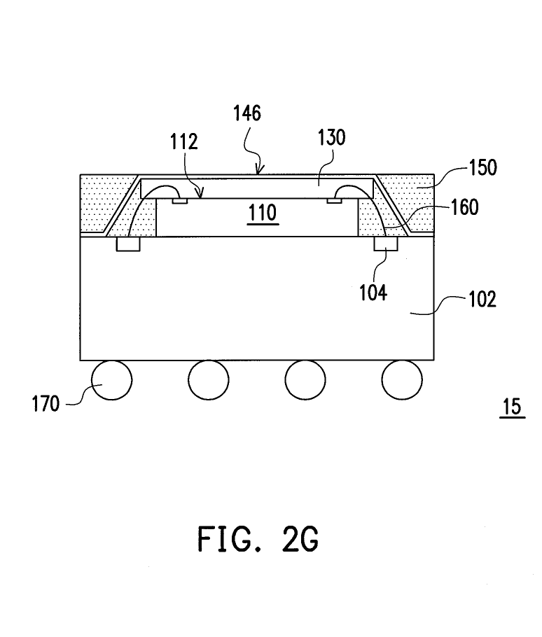

FIG. 1A is a top view of a package substrate according to one embodiment of the invention. FIGS. 2A-2E are schematic cross-sectional views of a chip scale packaging process according to one embodiment of the invention. Referring to FIG. 1A, the package substrate 100 has a plurality of blocks 101, and each block includes a plurality of substrate units 102 on which a plurality of chips 110 are mounted. The dotted lines represent the cutting lines for the cutting tool to separate the substrate units 102. The mounted chip 110 is electrically connected to the substrate 100 either by wire-bonding technology or flip chip technology. According to this embodiment, a single chip is mounted to each substrate unit in a one-to-one mode. However, if a stack chip package or the multi-chip package is desirable, multiple chips can be mounted to one substrate unit.

FIG. 2A shows an example of a schematic cross-sectional view of the single substrate unit 102 in FIG. 1A. As shown in FIG. 2A, the chip 110 is mounted on the substrate unit 102 of the provided substrate 100. The substrate 100 can be, for example, a multiple-layer circuit substrate of which the outermost layer has a plurality of contacts 104. For simplicity sake, the protective layer of soldermask over the traces leading to the contacts 104 has been omitted. Likewise, the traces/contacts are usually riding ontop of the substrate rather than being buried in the substrate as shown here. Those contacts 104 can be arranged on chip bonding regions of the substrate 100 in various manners depending on the applications or design needs. Each chip 110 has an active surface 112 and a back surface 114 opposite to the active surface 112. A plurality of bumps 120 are formed on the active surface 112 corresponding to the contacts 104 in the chip bonding regions of the substrate 100, so that the chips 110 are electrically connected to the substrate 100 through bumps 120.

As shown in FIG. 2A, in order to reduce damage to the chips 110 and the substrate 100 due to differential coefficient of thermal expansion between the chip 110 and the substrate 100, an underfill 122 may be optionally filled between the chips 110 and the substrate 100. However, owing to the potential overflow issues of the underfill, it is preferable to skip the step of filling the underfill 122 in the present invention.

Referring to FIG. 2B, a matrix heat sink 140 is placed over the chips 110 with a bond film 130 in-between. For example, the matrix heat sink 140 includes a plurality of heat sink units 142 which are inter-linked with one another to form a web-like network, as shown in FIG. 1B. According to FIG. 1B, each heat sink unit 142 includes a body 142a and a plurality of legs 142b connected to the body 142a, and each heat sink unit 142 is inter-linked with one another via the legs 142b. That is, the legs 142b of a single heat sink unit 142 are connected with those of adjacent heat sink units 142. The material of the matrix heat sink 140 can be copper, nickel, copper plated with nickel, the alloys thereof or any other suitable metals, for example. On the other hand, ceramic type matrix heat sink made of silicon carbide or other ceramic materials of high thermal conductivity may be used. The shape of the body 142a can be, for example, round, square, triangular, rectangular or polygonal, and the number of the legs 142b is not limited to four, six or eight, but can be any integer larger than 1. The size or pattern of the heat sink unit 142 and/or the body 142a can be modified depending on the design requirements of the package structure 10, while the area ratio of the body 142a/legs 142b can be adjusted or tailored for reaching desirable heat dissipation efficiency in the package structure.

When the matrix heat sink 140 is placed over the chips 110, each heat sink unit 142 corresponds to one chip 110 and the body 142a of the heat sink unit 142 is attached to the back surface 114 of the chip via the bond film 130. Preferably, before placing the matrix heat sink 140 over the chip 110, the bond film 130 is disposed on an inner surface 140a of the matrix heat sink 140. Alternatively, the bond film 130 can be placed on the back surfaces 114 of the chips 110 before placing the matrix heat sink 140. The bond film 130 can be, for example, a film-type adhesive or a film-over-wire (FOW) die attach film.

In FIG. 2C, the planar matrix heat sink 140 is pressed into a down-set heat sink structure 144 to form a plurality of three-dimensional heat sink units 146, by a stamping process, and then cover the chip 110 and some of the contacts 104 of the package substrate 100. The planar heat sink unit 142 is pressed against the chip 110 where the resultant body 146a remains planar, but the legs 142b is bent down to form a slant portion 146b and an extended portion 146c of the three-dimensional heat sink unit 146. The slant portion 146b is located between the body 146a and the extended portion 146c, and the extended portion 146c is disposed on the substrate 100. After a curing or reflow process, the down-set heat sink structure 144 is attached to the substrate 100 via solders or glues 126, for example. The glues or solders 126 can be dispensed on the substrate 100 or on the matrix heat sink 140 prior to the stamping process. Hence, the down-set heat sink structure 144 is thermally connected to the substrate 102. Optionally, the down-set heatsink 144 can be electrically and thermally connected to the substrate unit 102 through one or more contacts 104 to provide grounding or shielding.

Referring to FIG. 2D, a molding compound 150 is applied over the top surface of the package substrate 100 to cover the down-set heat sink structure 144 and the underlying chips 110 and the top surface of the substrate 100, by a molding process. If the optional step of filling the underfill 112 is omitted, the molding compound 150 also covers the bumps 120 and the contacts 104 of the substrate 100, which is the so-called mold-only approach. Preferably, the top (outer) surface 144b of the body 146a within the heat sink structure 144 is exposed by the molding compound for better heat dissipation. The molding compound 150 can be a polymeric resin. Moreover, thermally conductive fillers, such as aluminum nitride particles, alumina (aluminum oxide) particles, boron nitride particles, carbon nanotubes or other suitable fillers of high thermal conductivity, can be added into the molding compound 150 to enhance the efficiency of heat dissipation.

Referring to FIG. 2E, after forming solder balls 170, the molded package structure 10 is singulated along the cutting lines (the dotted lines) by dicing or sawing, for example, and a plurality of individual package unit structures 15 is obtained (FIG. 2F). Each package unit structure 15 includes at least a substrate unit 102, a chip 110, a three-dimensional heat sink unit 146 and a portion of the molding compound 150.

Referring to FIG. 2F, for the package unit structure 15, the heat sink unit 146 is disposed on the substrate units 102 and covers the chip 110. The body 146a is adhered to the chip via the bond film 130, while the outer surface 144b of the body 146a is exposed. The slant portion 146b, embedded in the molding compound 150, connects the body 146a and the extended portion 146c. The extended portion 146c disposed on the top surface of the substrate unit 102 is covered by the molding compound 150, but a tail end 147 of the extended portion 146c is exposed by the sidewall 150a of the molding compound 150. As the individual package unit structure 15 is obtained by cutting through the substrate 100, the heat sink structure 144 and the molding compound 150, the sidewall 150a of the molding compound 150 is aligned with and coplanar with the sidewall 102a of the substrate unit 102.

Alternatively, the package unit structure 15 as shown in FIG. 2G is similar to the package unit structure 15 of FIG. 2F, except for the chip 110 is directly disposed on the substrate unit 102 and is electrically connected to the substrate unit 102 via wires 160. For the package unit structure 15 in FIG. 2G, the bond film 130 is placed on the active surface 112 of the chip 110, and the bond film can be, for example, a film-over-wire (FOW) die attach film. Since the material of the FOW film is designed to flow over and wrap around the wires of the chip, the position or the size of the bond film can be more flexible without disturbing the arrangements of the wires.

In contrast to the inefficient and time-consuming process of placing individual heat sink, the placement/attachment of the interconnected matrix heat sink in the present invention is easy and straightforward and the usage of matrix heat sink is compatible with the existing packaging processes. Further, the interconnected matrix heat sink can be designed as open tools to be more cost-effective.

By using the bond films of uniform thickness and adequate flow ability, there is no need to use extra adhesives to fixate the heat sink before molding, thus improving the yield and production. The bond film can maintain a well-controlled spacing between the matrix heat sink and the individual chips for the flip chip package structure. As for the wire-bonding package structure, the bond films can flow over the chips without disturbing the wires and properly fill the gap between the heat sink and the chips. Hence, the reliability of the package structures according to the present invention can be effectively increased.

As described herein, the effectiveness of heat dissipation for the package structure can be further improved by adding thermally enhanced fillers into the molding compounds and/or the bond film.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip scale package structure, comprising:
a substrate unit having a mounting surface and a back surface;
a chip, mounted on the mounting surface of the substrate unit;
a heat sink, disposed on the chip with a bond film in-between, wherein the heat sink has a body portion located on top of and attached to the chip, an extended portion attached to the substrate unit and a slant portion connecting the body portion and the extended portion;
a molding compound covering the heat sink and filling between the heat sink, the chip and the substrate unit, wherein an end of the extended portion of the heat sink is exposed from the molding compound and a sidewall of the molding compound is aligned with a sidewall of the substrate unit; and
at least a solder ball, disposed on the back surface of the substrate unit.

2. The package structure of claim 1, wherein the chip is electrically connected to the substrate unit through a plurality of bumps in-between.

3. The package structure of claim 2, further comprising an underfill between the chip and the substrate unit and encapsulating the bumps.

4. The package structure of claim 2, wherein a top surface of the body portion of the heat sink is exposed by the molding compound.

5. The package structure of claim 1, wherein the chip is electrically connected to the substrate unit through a plurality of wires.

6. The package structure of claim 1, wherein the body portion of the heat sink is attached to the chip via a bond film in-between.

7. The package structure of claim 6, wherein the bond film comprises a film-over-wire (FOW) film.

8. The package structure of claim 1, wherein the molding compound further comprises thermally conductive fillers.

9. The package structure of claim 8, wherein thermally conductive fillers are made from aluminum nitride particles, alumina particles, boron nitride particles or carbon nanotubes.

10. The package structure of claim 1, wherein a shape of the body portion for the heat sink is round, triangular, square, rectangular or polygonal.

11. A packaging process, comprising:
providing a substrate, wherein the substrate comprises a plurality of substrate units;
mounting a plurality of chips to the substrate units of the substrate, wherein each substrate unit is mounted with at least one chip;
placing and attaching a matrix heat sink on the chips and over the substrate, wherein the matrix heat sink comprises a plurality of heat sink units interlinked with one another, each heat sink unit corresponds to one chip;
forming a molding compound over the substrate and covering the matrix heat sink, the chips and the substrate units;
forming a plurality of solder balls on a back surface of the substrate; and
cutting through the molding compound, the matrix heat sink and the substrate to form a plurality of package units, wherein each package unit comprises a portion of the molding compound, a heat sink unit, a chip, a substrate unit and a solder ball.

12. The process of claim 11, wherein the step of placing and attaching the matrix heat sink further comprises forming a bond film on an inner surface of the matrix heat sink.

13. The process of claim 11, wherein the step of placing and attaching the matrix heat sink further comprises forming a bond film on top of the chip.

14. The process of claim 11, further comprising forming a plurality of bumps between the chip and the substrate unit before mounting the chips to the substrate.

15. The process of claim 14, further comprising forming an underfill between the chip and the substrate unit and encapsulating the bumps.

16. The process of claim 11, further comprising forming a plurality of wires between the chip and the substrate unit after mounting the chips to the substrate.

17. A package structure, comprising:
a substrate having a plurality of substrate units;
a plurality of chips, wherein at least one chip is mounted on each substrate unit;
a matrix heat sink disposed over the substrate and covering the chips, wherein the matrix heat sink comprises a plurality of heat sink units interlinked with one another, each heat sink unit corresponds to one chip, and each heat sink unit has a body portion located on top of and attached to the chip, an extended portion attached to the substrate unit and a slant portion connecting the body portion and the extended portion;
a molding compound covering the substrate and the matrix heat sink and filling between the matrix heat sink, the chips and the substrate; and
a plurality of solder balls disposed on a back surface of the substrate.

18. The package structure of claim 17, wherein the chip is electrically connected to the substrate unit through a plurality of bumps in-between.

19. The package structure of claim 18, wherein a top surface of the body portion of the heat sink unit is exposed by the molding compound.

20. The package structure of claim 17, wherein the chip is electrically connected to the substrate unit through a plurality of wires.

21. The package structure of claim 17, wherein the body portion of the heat sink unit is attached to the chip via a bond film in-between.

22. The package structure of claim 21, wherein the bond film comprises a film-over-wire (FOW) film.

23. The package structure of claim 17, wherein the molding compound further comprises thermally conductive fillers.

24. The package structure of claim 23, wherein thermally conductive fillers are made from aluminum nitride particles, alumina particles, boron nitride particles or carbon nanotubes.
